(19) United States
(12) Patent Application Publication
(10) Pub. No.: US 2026/0205111 A1
(43) Pub. Date: Jul. 16, 2026

(54) RELAY USING INSULATOR-METAL TRANSITION

(71) Applicant: UIF (University Industry Foundation), Yonsei University, Seoul (KR)

(72) Inventors: Honglyoul JU, Seoul (KR); Gi Yong LEE, Yongin-si, Gyeonggi-do (KR)

(21) Appl. No.: 19/428,235

(22) Filed: Dec. 21, 2025

(30) Foreign Application Priority Data
Jan. 7, 2025 (KR) 10-2025-0002155

(51) Int. Cl. H03K 17/51

(52) U.S. Cl. CPC H03K 17/51

(57) ABSTRACT

A phase-transition relay using an insulator-metal transition (IMT) material is disclosed. The relay includes a first circuit having first and second IMT elements connected in parallel, a coil generating a magnetic field when the first circuit is turned on, and an armature that changes a contact state in response to the magnetic field. The first IMT element undergoes a phase transition to a metallic state upon light application to turn on the first circuit. The second IMT element also transitions to a metallic state upon light application to distribute current flowing through the first IMT element. This distribution causes both IMT elements to return to an insulating state, thereby turning off the first circuit. The relay further includes a second circuit with contacts that open or close based on the armature's movement.

### CROSS-REFERENCE TO RELATED APPLICATION

This application claims priority under 35 U.S.C. §119(a) to Korean Patent Application No. 10-2025-0002155, filed on Jan. 7, 2025, in the Korean Intellectual Property Office, the disclosure of which is incorporated herein in its entirety by reference.

### BACKGROUND

The disclosure relates to a relay, and more particularly, to a relay using insulator-metal transition (IMT).

IMT materials undergo a phase transition from an insulator to a metal or from a metal to an insulator according to given conditions or environments. Among these IMT materials, vanadium dioxide (VO₂) is currently being studied most actively. As the only IMT material having a transition temperature close to room temperature, VO₂ is expected to be used in various electrical and electronic devices because most applications, such as sensors, semiconductor elements, and optical elements, operate at a temperature near room temperature. In particular, VO₂ undergoes a change in resistance not only due to temperature but also due to various external stimuli, such as electricity, light, and stress, thereby causing a phase transition between an insulator and a metal. Therefore, there has been active research into various devices using VO₂.

Relays are electromagnetic devices that act as switches opening and closing circuits by using electrical signals. Relays are usually used to control large current or voltage through small current or voltage and used as crucial components in various electrical and electronic systems.

### SUMMARY

The disclosure provides a phase-transition relay for controlling high voltage (or current) with low voltage (or current) by using a phase transition of an insulator-metal transition (IMT) material.

The disclosure also provides a phase-transition relay that is based on the phase transition of an IMT material and is driven at high speed by pulsed light without a distance limit.

According to an aspect of the disclosure, there is provided a phase-transition relay including a first circuit and a second circuit, wherein the first circuit includes a first IMT element including an IMT material, the first IMT element being configured to undergo a phase transition to a metal when light is applied to the first IMT element and turn on the first circuit, a second IMT element electrically connected in parallel to the first IMT element and including the IMT material, the second IMT element being configured to undergo a phase transition to a metal when light is applied to the second IMT element, disperse current flowing through the first IMT element, undergo a phase transition to an insulator together with the first IMT element due to the dispersed current, and turn off the first circuit, a coil connected to the first IMT element and the second IMT element and configured to generate a magnetic field when the first circuit is turned on, and an armature configured to change a contact state according to the magnetic field generated in the coil, and the second circuit includes contacts configured to be closed or opened according to a movement of the armature of the first circuit.

According to another aspect of the disclosure, there is provided a phase-transition relay including a first circuit and a second circuit, wherein the first circuit includes an IMT element including an IMT material, the IMT element being configured to undergo a phase transition to a metal when light is applied to the IMT element and turn on the first circuit, a coil connected to the IMT element and configured to generate a magnetic field when the first circuit is turned on, and an armature configured to change a contact state according to the magnetic field generated in the coil, and the second circuit includes contacts configured to be closed or opened according to a movement of the armature of the first circuit.

### BRIEF DESCRIPTION OF THE DRAWINGS

Embodiments of the disclosure will be more clearly understood from the following detailed description taken in conjunction with the accompanying drawings in which:

FIG. 1 is a circuit diagram of a phase-transition relay using an insulator-metal transition (IMT), according to an embodiment of the present disclosure;

FIG. 2 illustrates an IMT element in FIG. 1;

FIG. 3 is a circuit diagram of a phase-transition dual relay according to an embodiment of the present disclosure;

FIG. 4 is a circuit diagram of a phase-transition relay according to some embodiments of the present disclosure;

FIGS. 5 and 6 are diagrams illustrating the turn-on mechanism and turn-off mechanism of a phase-transition relay using an IMT, according to an embodiment of the present disclosure;

FIGS. 7 and 8 are diagrams showing a comparison of a parallel structure of IMT elements having the same sizes with a parallel structure of IMT elements having different sizes in a phase-transition relay using an IMT, according to an embodiment of the present disclosure; and

FIG. 9 is a circuit diagram of a phase-transition relay according to some embodiments of the present disclosure.

### DETAILED DESCRIPTION OF THE EMBODIMENTS

The accompanying drawings for illustrating embodiments are referred to in order to gain a sufficient understanding of the disclosure, the merits thereof, and the objectives accomplished by the implementation of the disclosure.

Hereinafter, the disclosure will be described in detail by explaining embodiments with reference to the accompanying drawings. However, the disclosure may be embodied in many different forms and should not be construed as limited to the embodiments set forth herein. In order to clearly explain the disclosure, parts unrelated to the descriptions are omitted, and like reference numerals in the drawings denote like elements.

Embodiments and terms used herein are not intended to limit the technology described herein to specific embodiments but will include any modifications, equivalents, and/or substitutes.

In the description of the disclosure, when the detailed description of the known functions or configurations in the related art may blur the gist of the disclosure, the detailed description thereof will be omitted.

In the description of the drawings, similar reference numerals may denote similar elements.

As used herein, the singular forms are intended to include the plural forms as well unless the context clearly indicates otherwise.

Expressions, such as “A or B” and “at least one of A and/or B”, may include all possible combinations of all items listed together.

When it is said that an element (e.g., a first element) is “(functionally or communicatively) connected or coupled to” another element (e.g., a second element), the element may be connected to the other element directly or through another element (e.g., a third element).

The terms “comprise” and “include” used herein should not be construed to necessarily include all of the elements or operations described herein, and some of the elements or operations may not be included, or additional elements or operations may be further included.

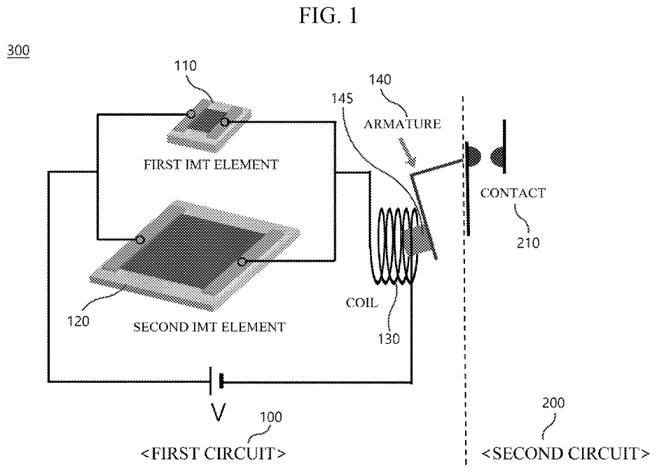

FIG. 1 is a circuit diagram of a phase-transition relay using an insulator-metal transition (IMT), according to an embodiment of the present disclosure.

A phase-transition relay 300 of FIG. 1 may include a first circuit 100 and a second circuit 200. The first circuit 100 may include a low-voltage circuit (in mA), and the second circuit 200 may include a high-voltage circuit (in A).

The first circuit 100 may include a first IMT element 110, a second IMT element 120, a coil 130, an armature 140, and a permanent magnet 145. An IMT element refers to an element that includes an IMT material and undergoes a phase transition to a metal when light is applied to the IMT element. In the embodiments below, vanadium dioxide (VO₂) is used as an example of an IMT material. VO₂ is a material that undergoes a change in resistance not only due to temperature but also due to various external stimuli, such as electricity, light, and stress, thereby causing a phase transition between an insulator and a metal.

The first IMT element 110 and the second IMT element 120 may include VO₂ on Corning glass substrates, respectively, which include the same material. The area of a phase-transition layer of the first IMT element 110 may be smaller than the area of a phase-transition layer of the second IMT element 120.

When the types of substrates of the first IMT element 110 and the second IMT element 120 are different, the phase-transition layers of the first IMT element 110 and the second IMT element 120 may be configured to have the same area. To effectively disperse current when light is radiated to the second IMT element 120, a very thin substrate or a substrate having different thermal conductivity than a substrate of the first IMT element 110 may be used for the second IMT element 120.

The first IMT element 110 and the second IMT element 120 may be connected in parallel. When both the first IMT element 110 and the second IMT element 120 are in an insulator state, an element voltage V may be applied to both the first IMT element 110 and the second IMT element 120.

When the size of the phase-transition layer of each of the first IMT element 110 and the second IMT element 120 is adjusted, the magnitude of a voltage applied to each of the first IMT element 110 and the second IMT element 120 may also be adjusted. Since the second IMT element 120 requires only a difference in electrical conductivity caused by pulsed light, VO₂ may be replaced with another semiconductor in the second IMT element 120.

When light having intensity higher than a threshold value is applied to the first IMT element 110, the first IMT element 110 may undergo a phase transition to a metal, thereby turning on the first circuit 100. In an embodiment, 405 nm-semiconductor laser light having an intensity of 8.9×106 Wm⁻² and a pulse width of 120 μs may be applied to the first IMT element 110. When light is applied to the second IMT element 120, the second IMT element 120 may undergo a phase transition to a metal and thus disperse the current flowing through the first IMT element 110. Due to the dispersed current, the second IMT element 120 may undergo a phase transition to an insulator together with the first IMT element 110, thereby turning off the first circuit 100. In an embodiment, 405 nm-semiconductor laser light having an intensity of 8.9×106 Wm⁻² and a pulse width of 6 ms may be applied to the second IMT element 120. A reflector may be mounted on the bottom of each of the first IMT element 110 and the second IMT element 120 to increase the amount of light absorbed by the first IMT element 110 or the second IMT element 120.

The coil 130 may be connected to the first IMT element 110 and the second IMT element 120 and may generate a magnetic field when the first circuit 100 is turned on. The coil 130 may also function as a resistor and thus prevent large current from suddenly flowing to the first circuit 100 when the first circuit 100 is turned on. The coil 130 may have a coreless structure and may have a large number of turns per unit length (e.g., 1.2×104/cm) to generate a magnetic field large enough to attract the permanent magnet 145 attached to the armature 140. With a current of 1 mA, the coil 130 may generate a magnetic field of about 10 Gauss. Alternatively, the coil 130 may have a structure having an ultrahigh-purity iron core, in which a saturation magnetic field is very small (<10 Gauss). In this case, an iron plate instead of the permanent magnet 145 may be attached to the armature 140. Inductive effect may be reduced by reducing the cross-sectional area of the coil 130.

Since the permanent magnet 145 is attached to the armature 140, an attractive force may be generated when a magnetic field is generated in the coil 130 so as to connect contacts 210 of the second circuit 200. When the contacts 210 of the second circuit 200 are connected, a current path may be formed in the second circuit 200. That is, the second circuit 200 may be turned on and driven.

In the phase-transition relay 300 of FIG. 1, the armature 140 and the contacts 210, which are driven by a magnetic field generated in the coil 130, may be replaced with a reed switch (not shown), which is driven by the magnetic field of the coil 130. When the magnetic field is generated in the coil 130, the reed switch may be turned on such that a current path is formed in the second circuit 200. That is, just like the case of the contacts 210, the second circuit 200 may be turned on and driven. Accordingly, the reed switch may be considered as an element of the second circuit 200 in the same way as the contacts 210.

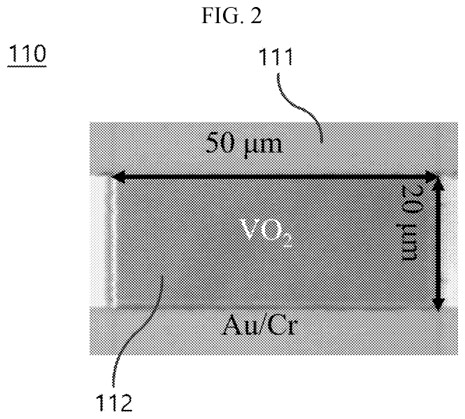

FIG. 2 illustrates an IMT element in FIG. 1.

FIG. 2 shows the size of the first IMT element 110. The first IMT element 110 may include chromium/gold electrodes 111 respectively on opposite ends of a substrate (not shown) and a phase-transition layer between the chromium/gold electrodes 111. The phase transition layer may include VO₂.

The first IMT element 110 may be formed to have a small size (e.g., 20 μm(L)×50 μm(W)) so as to have a low threshold voltage, thereby facilitating a phase transition.

Although not shown, the second IMT element 120 may be formed to have a large size (e.g., 300 μm×300 μm) so as to have a high threshold voltage, thereby making it difficult to cause a phase transition.

Although not shown, each of the first IMT element 110 and the second IMT element 120 may include a reflector (not shown), which is attached to the bottom of the substrate. The reflector may have a circular or parabolic shape such that light passing the first IMT element 110 and the second IMT element 120 may be sent back to the first IMT element 110 and the second IMT element 120 by the reflectors respectively below the first IMT element 110 and the second IMT element 120. This may increase the light absorption efficiency of an IMT element.

According to an embodiment, the same wavelength may be used for the first IMT element 110 and the second IMT element 120, or pulsed light beams having different wavelengths may be respectively applied to the first IMT element 110 and the second IMT element 120. When an optical path is properly designed, it may be possible to direct one wavelength to the first IMT element 110 and another wavelength to the second IMT element 120 when light is applied to the same location, due to the fact that a refractive index varies with a wavelength.

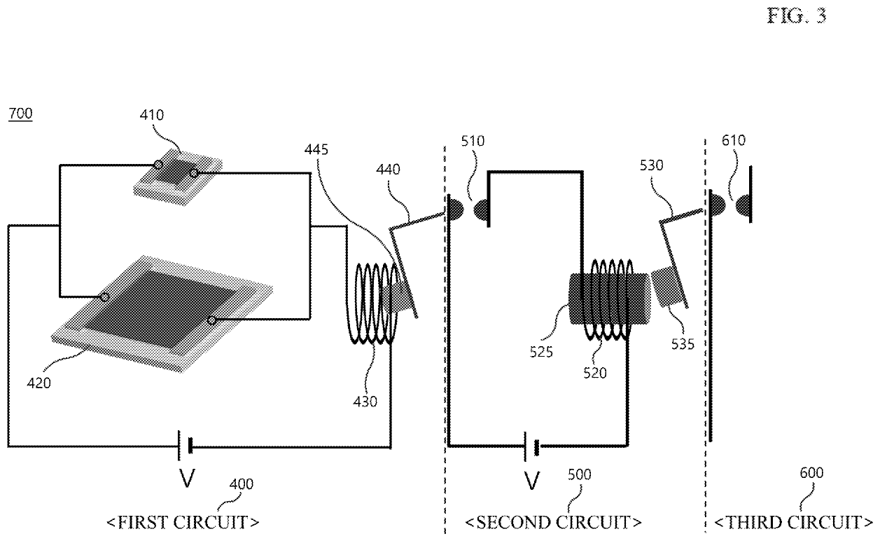

FIG. 3 is a circuit diagram of a phase-transition dual relay according to an embodiment of the present disclosure.

A phase-transition dual relay 700 of FIG. 3 may include a first circuit 400, a second circuit 500, and a third circuit 600. The first circuit 400 may include a low-voltage circuit on the order of about several mA, the second circuit 500 may include a low-voltage circuit on the order of about several A, and the third circuit 600 may include a high-voltage circuit on the order of about several kA.

The first circuit 400 may include a first IMT element 410, a second IMT element 420, a coil 430, an armature 440, and a permanent magnet 445. Detailed description of each element is omitted as the description given with reference to FIG. 1 may be identically or similarly applied.

The second circuit 500 may include a coil 520, which has an iron core 525 generating a magnetic field when the second circuit 500 is turned on due to the closing of contacts 510 of the second circuit 500, and an armature 530, which changes the state of contacts 610 of the third circuit 600 due to the core 525 magnetized by the magnetic field generated in the coil 520 of the second circuit 500. An iron plate 535 may be attached to the armature 530. When the second circuit 500 is turned on, the contacts 610 of the third circuit 600 may be closed.

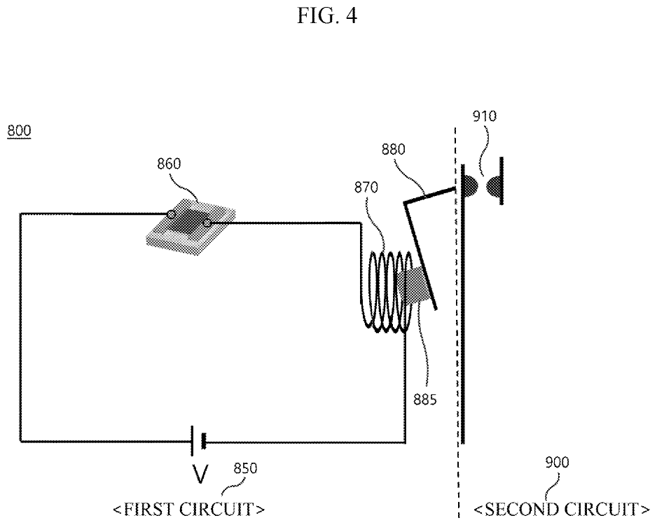

FIG. 4 is a circuit diagram of a phase-transition relay according to some embodiments of the present disclosure.

A phase-transition relay 800 may include a first circuit 850 and a second circuit 900. The first circuit 850 may include a low-voltage circuit (in mA), and the second circuit 900 may include a high-voltage circuit (in A).

The first circuit 850 may include an IMT element 860, a coil 870, an armature 880, and a permanent magnet 885.

Since the phase-transition relay 800 is used when only the turn-on function is required, the phase-transition relay 800 includes only one IMT element 860.

When the first circuit 850 is turned on by the phase transition of the IMT element 860, contacts 910 of the second circuit 900 may be closed.

Although not shown, even when a phase-transition relay performs only the turn-on function, the phase-transition relay may be implemented in a structure similar to that of a dual relay when a large current or voltage is required.

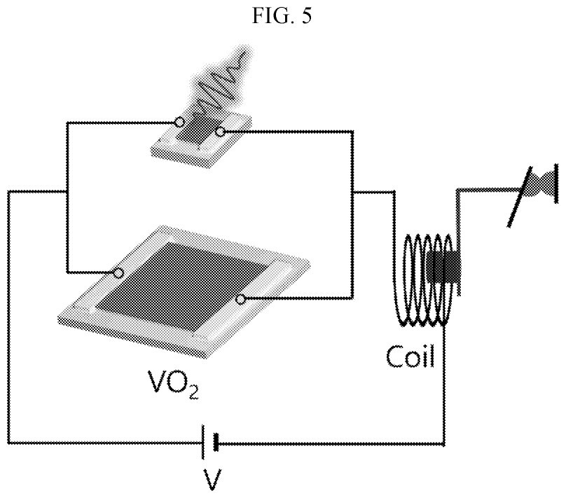

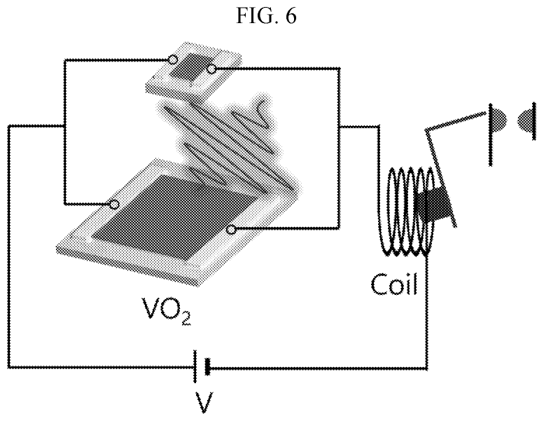

FIGS. 5 and 6 are diagrams illustrating the turn-on mechanism and turn-off mechanism of a phase-transition relay using an IMT, according to an embodiment of the present disclosure.

FIG. 5 illustrates the turn-on mechanism of a circuit, and FIG. 6 illustrates the turn-off mechanism of the circuit.

Referring to FIG. 1 for the turn-on mechanism, when pulsed light is applied to the first IMT element 110, an IMT may occur, significantly increasing current. The magnetic field of the coil 130 may attract the permanent magnet 145 of the armature 140 such that the contacts 210 are connected.

Referring to FIG. 1 for the turn-off mechanism, when pulsed light is applied to the second IMT element 120, a decrease in resistance may cause a majority of current to flow through the second IMT element 120 such that the second IMT element 120 undergoes a transition back to an insulator. The current flowing through the first IMT element 110 may fall below a minimum current required to maintain conductivity, causing the first IMT element 110 to become an insulator. As a result, the contacts 210 may be opened by a spring force.

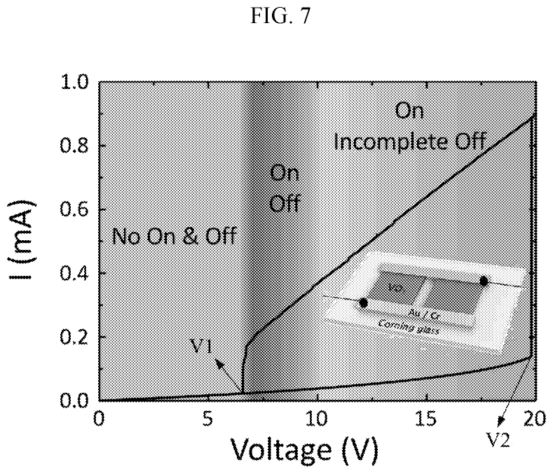

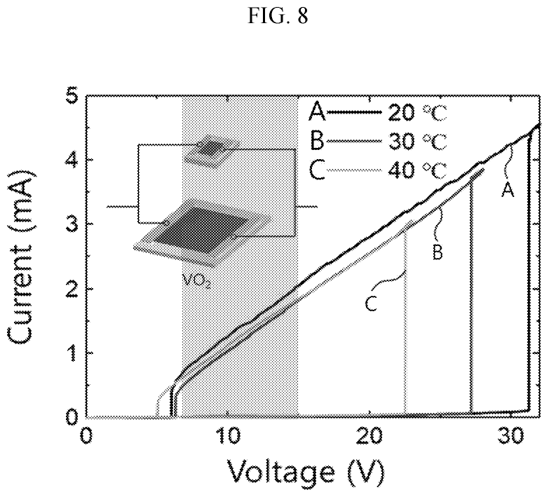

FIGS. 7 and 8 are diagrams showing a comparison of a parallel structure of IMT elements having the same sizes with a parallel structure of IMT elements having different sizes in a phase-transition relay using an IMT, according to an embodiment of the present disclosure.

FIG. 7 shows the on/off voltage ranges (measured at 30° C.) of two VO₂ elements having the same size (10 μm×40 μm), and FIG. 8 shows the on/off voltage ranges of two VO₂ elements having different sizes (20 μm×50 μm and 300 μm×300 μm).

FIG. 7 shows the voltage range in which a parallel structure of two VO₂ elements having the same size may be turned on or off. In this case, V1=6.9 V and V2=19.5 V, but the voltage range in which the two VO₂ elements may be turned on and off is between 7 V and 10 V. The voltage ranges in which the two VO₂ elements may be turned on and off at different temperatures rarely overlap. While the two VO₂ elements may be turned on and off at a measurement temperature of 30° C., it may be difficult to turn on and off the two VO₂ elements with the same voltage at different temperatures. FIG. 8 shows the voltage range in which a parallel structure of two VO₂ elements having different sizes may be turned on or off. At a voltage of 7 V to 15 V having a common hysteresis curve, the two VO₂ elements may be turned on and off regardless of temperature. This may be because when a first element is in a metal state, lowering the resistance of a second element makes it much easier to divert current flowing through the first element to the second element. There may be a difference between a common voltage range for on/off operation and a hysteresis common voltage range because a voltage is abruptly applied during on/off measurement whereas the voltage is gradually increased during hysteresis measurement. This may be because power dissipated as heat into a substrate when a sudden voltage is applied is relatively lower than that when a voltage is gradually applied, and accordingly, element temperature may rapidly rise, facilitating the occurrence of a phase transition.

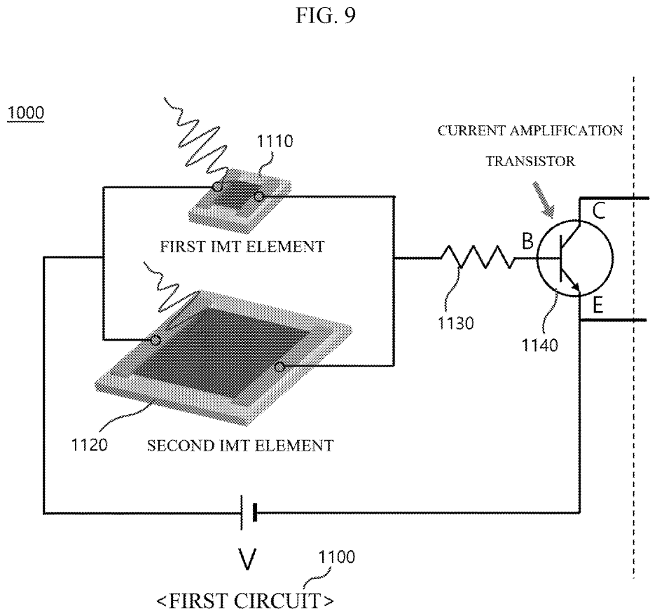

FIG. 9 is a circuit diagram of a phase-transition relay according to some embodiments of the present disclosure.

A phase-transition relay 1000 may include a first circuit 1100. Although not shown for convenience, the phase-transition relay 1000 may also include a second circuit (not shown). The first circuit 1100 may include a low-voltage circuit (in mA), and the second circuit may include a high-voltage circuit (in A).

The first circuit 1100 may include a first IMT element 1110, a second IMT element 1120, a resistor 1130, and a transistor 1140. The first and second IMT elements 1110 and 1120 may be configured and connected in parallel in the same manner as the first and second IMT elements 110 and 120 in FIG. 1, and thus descriptions thereof are omitted. However, in the embodiment of FIG. 9, the first circuit 1100 may include the transistor 1140 instead of the coil 130, the armature 140, and the contacts 210. The transistor 1140 may include a current amplification transistor. Since current flowing through a collector C and an emitter E of the transistor 1140 is controlled according to a voltage level applied to a base B of the transistor 1140 through the resistor 1130, the transistor 1140 may allow the amplified current to flow in the second circuit.

As described above, according to an embodiment, a relay using an IMT may control high voltage (or current) with low voltage (or current) by using a phase transition of an IMT material.

According to an embodiment, a device or equipment may be driven at high speed by using a phase-transition relay via pulsed light without a distance limit, based on the phase transition of an IMT material.

The relay using the IMT described above may not be limited to the configuration and method of the embodiments described above, and all or part of the embodiments may be selectively combined such that various modifications may be made therein.

What is claimed is:

1. A phase-transition relay comprising a first circuit and a second circuit,
wherein the first circuit includes:
a first insulator-metal transition (IMT) element including an IMT material, the first IMT element being configured to undergo a phase transition to a metal when light is applied to the first IMT element and turn on the first circuit;
a second IMT element electrically connected in parallel to the first IMT element and including the IMT material, the second IMT element being configured to undergo a phase transition to a metal when light is applied to the second IMT element, disperse current flowing through the first IMT element, undergo a phase transition to an insulator together with the first IMT element due to the dispersed current, and turn off the first circuit;
a coil connected to the first IMT element and the second IMT element and configured to generate a magnetic field when the first circuit is turned on; and
an armature configured to change a contact state according to the magnetic field generated in the coil, and
the second circuit includes contacts configured to be closed or opened according to a movement of the armature of the first circuit.

2. The phase-transition relay of claim 1, wherein the first circuit further includes a permanent magnet attached to an end of the armature.

3. The phase-transition relay of claim 1, wherein the first circuit further includes an iron plate attached to an end of the armature, and the coil of the first circuit has an iron core therein.

4. The phase-transition relay of claim 1, wherein the IMT material comprises vanadium dioxide (VO₂), and an impurity is added to the VO₂ to control a phase transition temperature of the IMT material, thereby expanding an operating temperature range of the phase-transition relay.

5. The phase-transition relay of claim 2, further comprising a third circuit including contacts configured to be closed or opened according to a magnetic field formed in the second circuit,
wherein the second circuit further includes:
a coil configured to generate the magnetic field when the second circuit is turned on by closing of the contacts of the second circuit; and
an armature configured to change a state of the contacts of the third circuit according to the magnetic field generated in the coil of the second circuit.

6. The phase-transition relay of claim 2, wherein each of the first IMT element and the second IMT element includes:
a substrate;
a phase-transition layer on the substrate and including the IMT material; and
an electrode at each of opposite ends of the phase-transition layer, and
a size of the phase-transition layer of the second IMT element is greater than a size of the phase-transition layer of the first IMT element.

7. The phase-transition relay of claim 2, wherein the first IMT element includes:
a first substrate;
a phase-transition layer on the first substrate and including the IMT material; and
an electrode at each of opposite ends of the phase-transition layer,
the second IMT element includes:
a second substrate;
a phase-transition layer on the second substrate and including the IMT material; and
an electrode at each of opposite ends of the phase-transition layer, and
the first substrate and the second substrate include materials having different thermal conductivities.

8. The phase-transition relay of claim 2, wherein each of the first IMT element and the second IMT element includes:
a substrate;
a phase-transition layer on the substrate and including the IMT material; and
an electrode at each of opposite ends of the phase-transition layer, and
a reflector is attached to a bottom of the substrate such that light absorption efficiency of each of the first IMT element and the second IMT element is increased.

9. A phase-transition relay comprising a first circuit and a second circuit,
wherein the first circuit includes:
an insulator-metal transition (IMT) element including an IMT material, the IMT element being configured to undergo a phase transition to a metal when light is applied to the IMT element and turn on the first circuit;
a coil connected to the IMT element and configured to generate a magnetic field when the first circuit is turned on; and
an armature configured to change a contact state according to the magnetic field generated in the coil, and
the second circuit includes contacts configured to be closed or opened according to a movement of the armature of the first circuit.

10. The phase-transition relay of claim 9, wherein the first circuit further includes a permanent magnet attached to an end of the armature.

11. The phase-transition relay of claim 9, wherein the first circuit further includes an iron plate attached to an end of the armature, and the coil of the first circuit has an iron core therein.

12. A phase-transition relay comprising a first circuit and a second circuit,
wherein the first circuit includes:
a first insulator-metal transition (IMT) element including an IMT material, the first IMT element being configured to undergo a phase transition to a metal when light is applied to the first IMT element and turn on the first circuit;
a second IMT element electrically connected in parallel to the first IMT element and including the IMT material, the second IMT element being configured to undergo a phase transition to a metal when light is applied to the second IMT element, disperse current flowing through the first IMT element, undergo a phase transition to an insulator together with the first IMT element due to the dispersed current, and turn off the first circuit; and
a transistor connected to the first IMT element and the second IMT element and configured to allow current having a magnitude corresponding to an applied voltage to flow in the second circuit when the first circuit is turned on.

13. A phase-transition relay comprising a first circuit and a second circuit,
wherein the first circuit includes:
a first insulator-metal transition (IMT) element including an IMT material, the first IMT element being configured to undergo a phase transition to a metal when light is applied to the first IMT element and turn on the first circuit;
a second IMT element electrically connected in parallel to the first IMT element and including the IMT material, the second IMT element being configured to undergo a phase transition to a metal when light is applied to the second IMT element, disperse current flowing through the first IMT element, undergo a phase transition to an insulator together with the first IMT element due to the dispersed current, and turn off the first circuit; and
a coil connected to the first IMT element and the second IMT element and configured to generate a magnetic field when the first circuit is turned on, and
the second circuit includes a reed switch configured to be turned on or off according to the magnetic field generated in the coil.
